(19) United States
(12) Patent Application Publication
(10) Pub. No.: US 2015/0189737 A1
(43) Pub. Date: Jul. 2, 2015

(54) METHOD FOR MANUFACTURING CONDUCTIVE PATTERN AND DEVICE HAVING CONDUCTIVE PATTERN

(71) Applicant: SAMSUNG DISPLAY CO., LTD., Yongin-City (KR)

(72) Inventors: BYEONG-JIN LEE, Suwon-Si (KR); Sung Ku Kang, Suwon-Si (KR); Jee-Hun Lim, Seongnam-Si (KR)

(73) Assignee: SAMSUNG DISPLAY CO., LTD., Yongin-City (KR)

(21) Appl. No.: 14/290,722

(22) Filed: May 29, 2014

(30) Foreign Application Priority Data
Dec. 30, 2013 (KR) 10-2013-0167497

(51) Int. Cl. H05K 1/02; H05K 3/06; G06F 1/16; H05K 1/09; G06F 3/044

(52) U.S. Cl. CPC H05K 1/028; H05K 1/097; H05K 1/0274; G06F 3/044; G06F 1/16; H05K 3/06; G06F 2203/04102; G06F 2203/04103

(57) ABSTRACT

A conductive pattern forming method includes forming a conductive layer on a substrate. An organic pattern including a plurality of fillers condensed in a network shape is formed on the conductive layer. A conductive pattern to which the shapes of the plurality of fillers condensed in the network shape are transferred is formed by dry-etching the conductive layer using the organic pattern as a mask. The organic pattern is eliminated.

### CROSS-REFERENCE TO RELATED APPLICATION

This application claims priority to and the benefit of Korean Patent Application No. 10-2013-0167497 filed in the Korean Intellectual Property Office on Dec. 30, 2013, the entire contents of which are herein incorporated by reference.

### TECHNICAL FIELD

The present invention relates to a conductive pattern, and more particularly, to a method for manufacturing a conductive pattern and a device including the conductive pattern.

### DISCUSSION OF THE RELATED ART

Flexible electronic devices may be produced by forming conductive patterns on flexible substrates that include a polyimide. These flexible electronic devices may also be foldable.

However, when the flexible electronic device is folded, high stress is applied to a conductive pattern at a bent portion of the flexible electronic device, thereby causing damage to the conductive pattern.

### SUMMARY

The present invention may provide a conductive pattern that can resist being damaged when bent or folded. A method is provided for forming the conductive pattern.

One aspect of the present invention provides a conductive pattern forming method. The conductive pattern forming method includes forming a conductive layer on a substrate. An organic pattern including a plurality of fillers condensed in a network shape is formed on the conductive layer. A conductive pattern to which the shapes of the plurality of fillers condensed in the network shape are transferred is formed by dry-etching the conductive layer using the organic pattern as a mask. The organic pattern is thereafter eliminated.

The conductive layer may include a transparent conductive material.

The filler may include a metal.

The metal may be silver (Ag).

The filler may be formed in the shape of a wire or particle.

The filler may be nano-sized.

The organic pattern may include a photoresist material.

The forming of the organic pattern may include forming an organic layer including a plurality of fillers on the substrate. The plurality of fillers may be condensed into a network shape by heating the organic layer. The organic layer may be pattered into the organic pattern.

The substrate may be a foldable and flexible substrate.

An aspect of the present invention provides an electronic device including a substrate and a conductive pattern located on the substrate. The shapes of the plurality of fillers condensed in the network shape are transferred.

The conductive pattern may include a transparent conductive material.

The filler may be nano-sized.

The substrate may be foldable and flexible.

An aspect of the present invention provides a method for forming a conductive pattern. The method includes forming a conductive layer on a substrate. A photoresist pattern is formed in a first area of the conductive layer. An organic pattern including a plurality of fillers condensed in a network shape is formed in a second area of the conductive layer. A first conductive pattern is formed in the first area by dry-etching the conductive layer using the photoresist pattern and the organic pattern as masks. A second conductive pattern to which the shapes of the plurality of fillers condensed in the network shape are transferred is formed in the second area. The photoresist pattern and the organic pattern are eliminated.

The conductive layer may include a transparent conductive material.

The filler may include a metal.

The metal may be silver (Ag).

The filler may be formed in the shape of a wire or particle.

The filler may be nano-sized.

The organic pattern may include a photoresist material.

The forming of the photoresist pattern and the organic pattern may include forming a photoresist layer on the substrate. The photoresist pattern is formed in the first area of the substrate by exposing and developing the photoresist layer. An organic layer including the plurality of fillers is formed on the substrate. The plurality of fillers is condensed into the network shape by heating the organic layer. The organic pattern is formed in the second area of the substrate by patterning the organic layer.

The substrate may be foldable and flexible.

An aspect of the present invention provides an electronic device including a substrate. A first conductive pattern is located in a first area of the substrate. A second conductive pattern is located in a second area of the substrate. Shapes of a plurality of fillers condensed in a network shape are transferred to the second area of the substrate.

The first conductive pattern and the second conductive pattern may respectively include transparent conductive materials.

The surface of the first conductive pattern may be flat.

The filler may be nano-sized.

The substrate may be foldable and flexible.

The second area may be a touch area where touch is recognized, and the first region may be an outer area neighboring the touch area.

The second conductive pattern may form a touch pad, and the first conductive pattern may form a wire connected with an end of the touch pad.

Exemplary embodiments of the present invention may provide a method for forming a conductive pattern such that damage to a conductive pattern at a bent portion formed due to bending of a flexible substrate may be prevented. An electronic device including conductive patterns can be provided.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 shows a method for forming a conductive pattern according to an exemplary embodiment of the present invention;

FIGS. 2 to 8 illustrate methods for forming conductive patterns according to exemplary embodiments of the present invention;

FIG. 9 is a cross-sectional view of an electronic device according to an exemplary embodiment of the present invention;

FIG. 10 is a cross-sectional view illustrating an effect of the electronic device according to exemplary embodiments of the present invention;

FIG. 11 is a flowchart illustrating a method for forming conductive patterns according to exemplary embodiments of the present invention;

FIG. 12 to FIG. 16 illustrate methods for forming conductive patterns according to exemplary embodiments of the present invention;

FIG. 17 is a cross-sectional view of a section of an electronic device according to an exemplary embodiment of the present invention; and

FIG. 18 is a top plan view of the electronic device of FIG. 17.

### DETAILED DESCRIPTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

Like reference numerals may designate like elements throughout the specification.

In addition, the size and thickness of each element shown in the drawings may be exaggerated for better understanding and ease of description, but the present invention is not limited thereto.

It will be understood that when an element such as a layer, film, region, or substrate is referred to as being “on” another element, it can be directly on the other element or intervening elements may also be present.

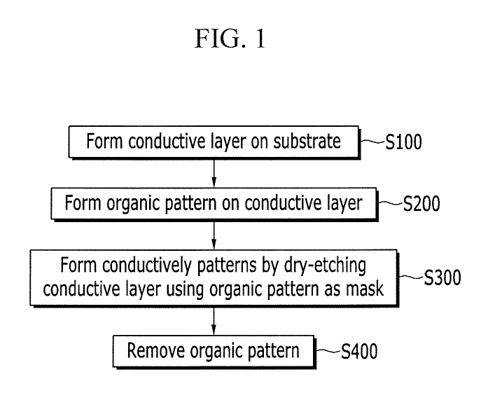

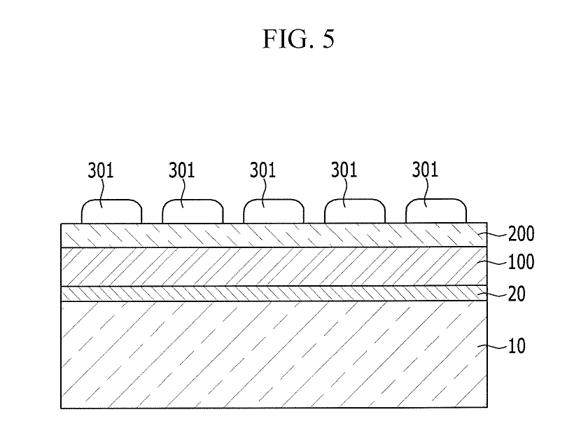

Hereinafter, a conductive pattern forming method according to an exemplary embodiment of the present invention will be described with reference to FIG. 1 to FIG. 8.

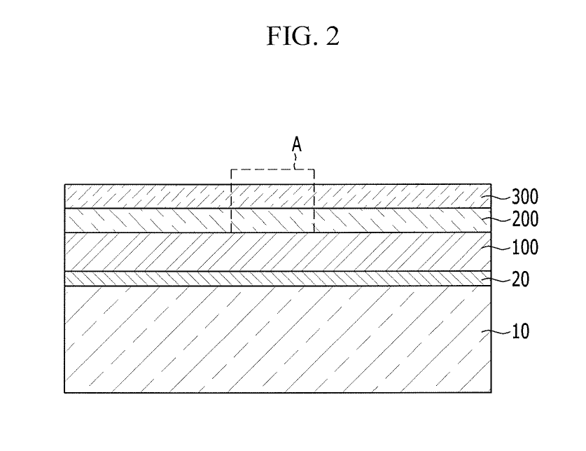

FIG. 1 is a flowchart illustrating a method for forming a conductive pattern according to an exemplary embodiment of the present invention. FIG. 2 to FIG. 8 are illustrations providing a description of the conductive pattern forming method according to the exemplary embodiment of the present invention.

First, as shown in FIG. 1 and FIG. 2, a conductive layer 200 is formed on a substrate 100 (S100).

In detail, the conductive layer 200 is formed on the substrate 100, and the substrate 100 is foldable and flexible. Here, the flexible substrate 100 may be a resin film such as a polyimide or a polycarbonate, and the conductive layer 200 may include a transparent conductive material such as indium tin oxide (ITO) and indium zinc oxide (IZO), or a metallic conductive material such as gold (Au), silver (Ag), molybdenum (Mo), aluminum (Al), and the like.

The flexible substrate 100 may be attached to a support substrate 10 including glass by an adhesive layer 20.

Next, as shown in FIG. 2 to FIG. 5, an organic pattern 301 is formed on the conductive layer 200 (S200).

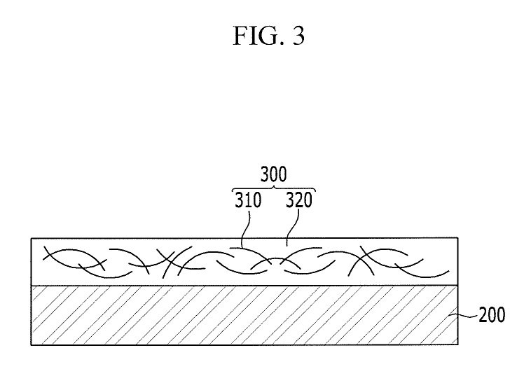

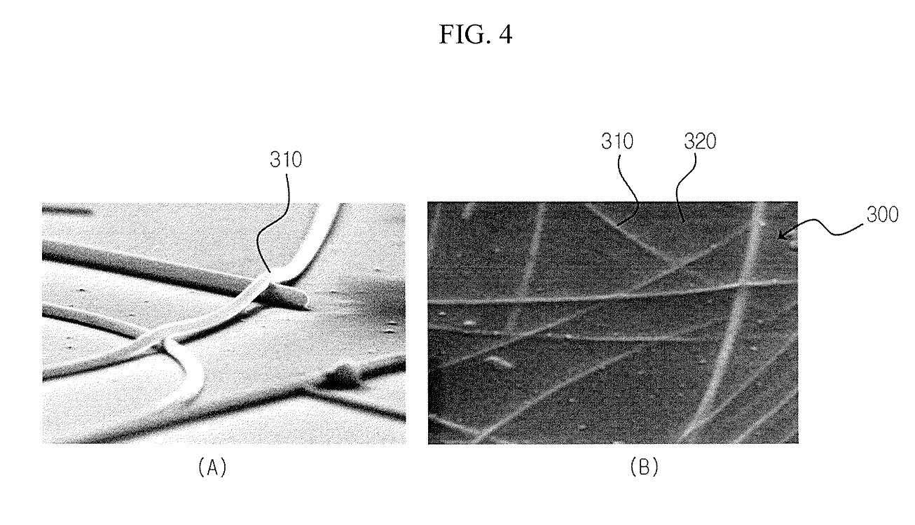

FIG. 3 is an enlarged view of the portion A of FIG. 2. In FIG. 4, (A) is a photograph of a filler and (B) is a photograph illustrating that the filler is located in an organic layer.

In detail, an organic layer 300 is formed on the substrate 100. The organic layer 300 may include a plurality of fillers 310 suspended in or covered by an overcoat layer 320. The organic layer 300 includes an organic material that includes a photoresist material. The fillers 310 located in the organic layer 300 may include nanoparticles or nanowires of metal such as silver (Ag). The invention is not limited to using fillers 310 of any particular shape or composition, and the fillers 310 may be composed of nano-sized objects of any shape or composition.

The organic layer 300 is heated to condense the plurality of fillers 310 in a network shape. The network shape may include, for example, multiple discrete clusters. If the filler 310 is formed as a large wire having a high aspect ratio, the plurality of fillers 310 can be condensed in a network shape without heating the organic layer 300, and in this case, a process for condensing the plurality of fillers 310 in a network shape by heating the organic layer 300 can be omitted.

The organic layer 300 is exposed and developed using a mask to pattern the organic layer 300 into organic patterns 301 such that the organic patterns 301 are formed on the conductive layer 200. The shape of the organic pattern 301 may vary according to the shape of a conductive pattern 201.

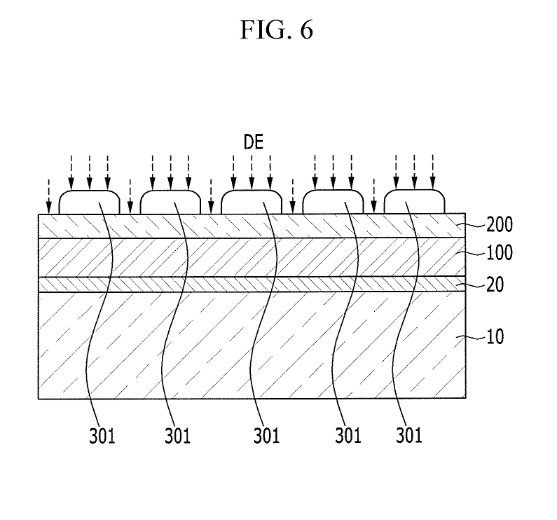

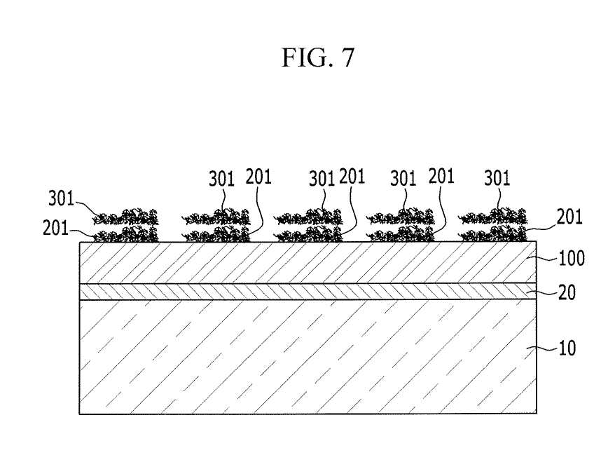

As shown in FIG. 6 and FIG. 7, the conductive layer 200 is dry-etched using the organic patterns 301 as a mask so as to form the conductive patterns 201 (S300).

In detail, the conductive layer 200 is dry-etched using the organic patterns 301 as a mask such that the conductive patterns 201 are formed. In this case, the dry-etching is performed throughout the substrate 100 using an etching means such as ions or plasma, and when the dry-etching is performed, an organic material included in the organic patterns 301 is substantially eliminated by the dry-etching and the plurality of fillers 310 condensed in the network shape are used as a mask such that the shapes of the fillers 310 condensed in the network shape are directly transferred as the shape of the dry-etched conductive patterns 201. Accordingly, the conductive patterns 201 are formed in the shape of the nano-sized fillers condensed in the network shape.

Since the conductive layer 200 is dry-etched by using the organic patterns 301 as a mask, the conductive patterns 201 are formed with shapes that are directly transferred from the plurality of fillers 310 condensed in the network shape.

After the conductive layer 200 is wet-etched using the organic patterns 301 as a mask, the dry-etching is performed throughout the substrate 100 so as to form the conductive patterns 201 with a shape that is transferred from the shape of the plurality of fillers 310 condensed in the network shape.

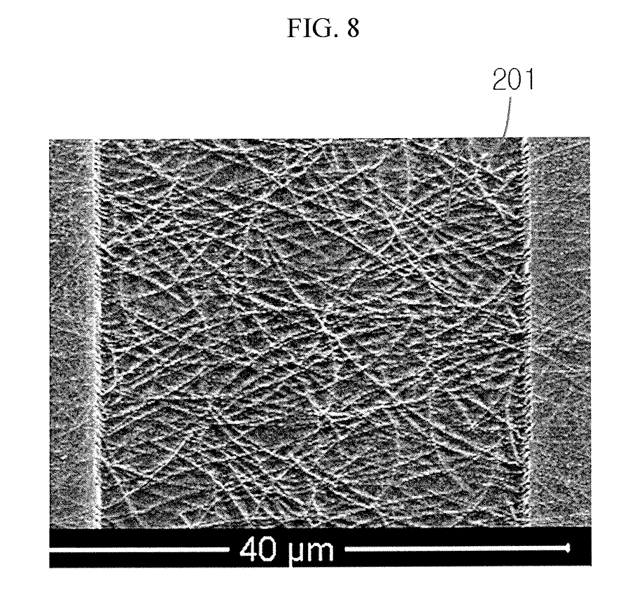

FIG. 8 is a plane view photograph illustrating the conductive patterns having the organic patterns removed.

As shown in FIG. 8, the organic patterns 301 are eliminated (S400).

In detail, a residual of the organic patterns 301 that include the plurality of fillers 310 is eliminated through an ashing process that uses plasma or the like such that the conductive patterns 201 are exposed.

An electronic device according to an exemplary embodiment of the present invention can be manufactured by detaching the substrate 100 from the support substrate 10.

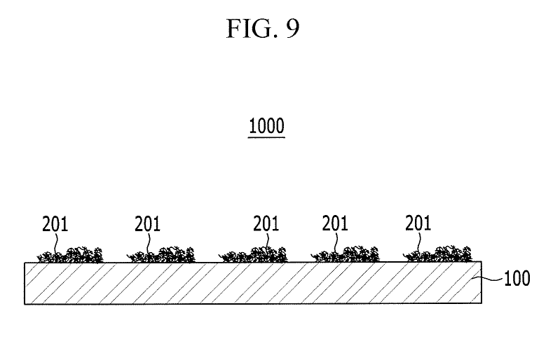

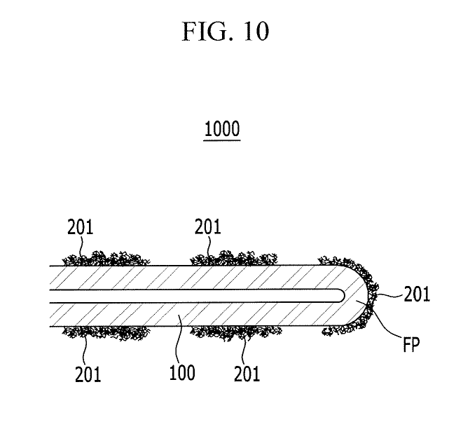

An electronic device according to an exemplary embodiment of the present invention will be described with reference to FIG. 9 and FIG. 10. An electronic device according to an exemplary embodiment of the present invention can be manufactured using a conductive pattern forming method such as those described herein.

FIG. 9 is a cross-sectional view of an electronic device according to an exemplary embodiment of the present invention.

As shown in FIG. 9, an electronic device 1000 includes a substrate 100 and conductive patterns 201.

The substrate 100 may be foldable and flexible. The flexible substrate 100 may include a resin film such as a polyimide or a polycarbonate.

The conductive patterns 201 are located on the substrate 100, and have shapes transferred from the shapes of a plurality of nano-sized fillers condensed in a network shape. The conductive patterns 201 may include a transparent conductive material such as indium tin oxide (ITO) and indium zinc oxide (IZO), or a metal conductive material such as gold (Au), sliver (Ag), molybdenum (Mo), aluminum (Al), and the like.

FIG. 10 is a cross-sectional view provided for description of an effect of the electronic device according to an exemplary embodiment of the present invention.

As shown in FIG. 10, the electronic device 1000 according to an exemplary embodiment of the present invention includes the flexible substrate 100 such that the electronic device 1000 can be folded. A bent portion FP of the folded electronic device 1000 has a significantly small curvature radius as compared to the thickness of the flexible substrate 100. As a result of the small curvature radius, a strong stress is applied to the conductive patterns 201 located in the bent portion FP of the folded electronic device 1000. However, the stress applied to the conductive patterns 201 can be dispersed because the shapes of the conductive patterns 201 are transferred from the shapes of the plurality of nano-sized fillers condensed in a network shape, and thus the conductive patterns 201 can be prevented from being damaged by the bending.

In particular, although the conductive patterns 201 may include indium tin oxide or indium tin oxide and thus may otherwise be easily damaged by stress compared to a metal such as silver (Ag), the conductive patterns 201 have the shape transferred from the shapes of the plurality of nano-sized fillers condensed in the network shape so that the stress applied to the conductive patterns 201 is dispersed, thereby suppressing the conductive patterns 201 from being damaged.

The electronic device 1000 according to exemplary embodiments of the present invention may be a touch panel or a display device, and the conductive patterns 201 may be touch pads included in the touch panel or pixel electrodes included in the display device. However, the invention is not restricted to this arrangement, and the electronic device may be used in various flexible electronic devices.

As described, the conductive pattern forming method that can suppress the conductive patterns 201 located in the bent portion FP of the folded flexible substrate 100 from being damaged and the electronic device including the conductive patterns 201 can be provided.

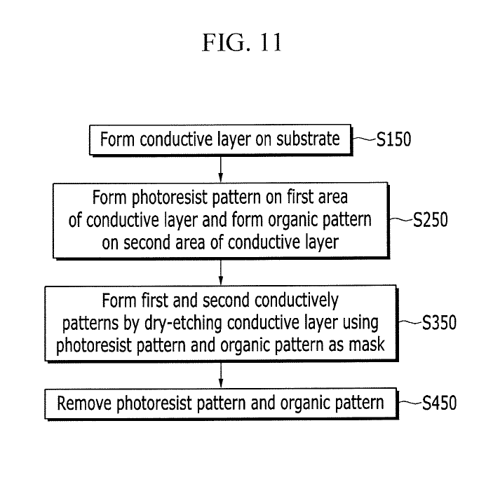

Hereinafter, a method for forming a conductive pattern according to an exemplary embodiment of the present invention will be described with reference to FIG. 11 to FIG. 16.

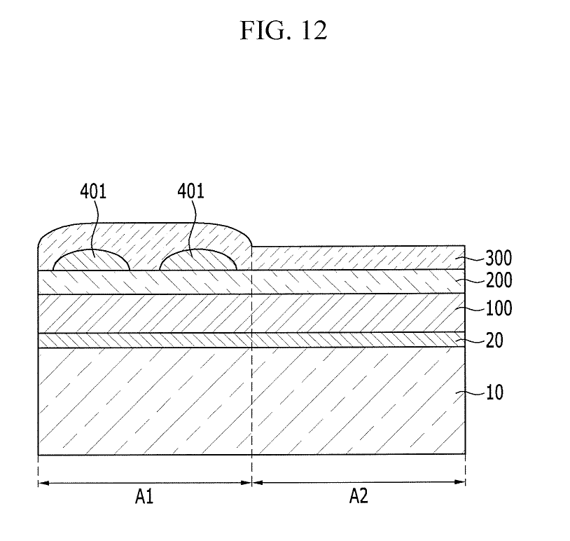

FIG. 11 is a flowchart of a conductive pattern forming method according to an exemplary embodiment of the present invention. FIG. 12 to FIG. 16 illustrate a method for forming a conductive pattern according to an exemplary embodiment of the present invention.

As shown in FIG. 11 and FIG. 12, a conductive layer 200 is formed on a substrate 100 (S150).

In detail, the conductive layer 200 is formed on a foldable and flexible substrate 100. Here, the flexible substrate 100 may be a resin film such as a polyimide or a polycarbonate, and the conductive layer may include a transparent conductive material such as indium tin oxide (ITO) and indium zinc oxide (IZO), or a metallic conductive material such as gold (Au), silver (Ag), molybdenum (Mo), aluminum (Al), or the like.

The flexible substrate 100 may be attached to a support substrate 10 including glass by an adhesive layer 20.

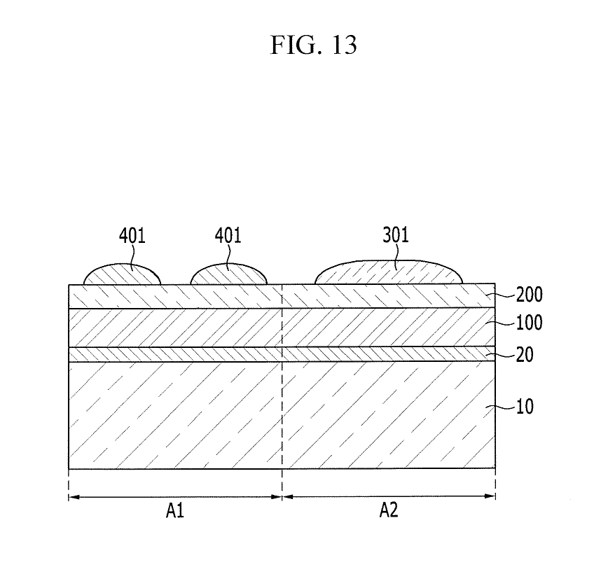

As shown in FIG. 12 and FIG. 13, photoresist patterns 401 are formed on a first area A1 of the conductive layer 200 and an organic pattern 301 is formed on a second area A2 of the conductive layer 200 (S250).

In detail, a photoresist layer is formed on the substrate 100 and the photoresist patterns 401 are formed on the first area A1 of the substrate 100 by exposing and developing the photoresist layer.

Then, the organic layer 300 including a plurality of fillers is formed on the substrate 100. The organic layer 300 includes an organic material including a photoresist material. The fillers located in the organic layer 300 may include a metal such silver (Ag), and are formed in the shape of a nanowire or nanoparticle. The material and the shape of the filler 310 are not limited to the shape and composition described herein, and any nano-sized objects may be used. The organic layer 300 may be heated to condense the plurality of fillers 310 in a network shape. If the filler 310 is formed as a large wire having a high aspect ratio, for example, where the length of the wire is very large as compared to its width, the plurality of fillers 310 can be condensed in a network shape without heating the organic layer 300, and in this case, a process for condensing the plurality of fillers 310 in a network shape by heating the organic layer 300 can be omitted. The organic layer 300 is exposed and developed using a mask to pattern the organic layer 300 on the second area A2 of the substrate 100 into the organic pattern 301 such that the organic pattern 301 is formed on the conductive layer 200 located in the second area A2 of the substrate 100. The shape of the organic pattern 301 may be varied according to the shape of the conductive pattern 201. In this case, the organic pattern 301 may be located on the photoresist pattern 401 located in the first area A1 of the substrate 100.

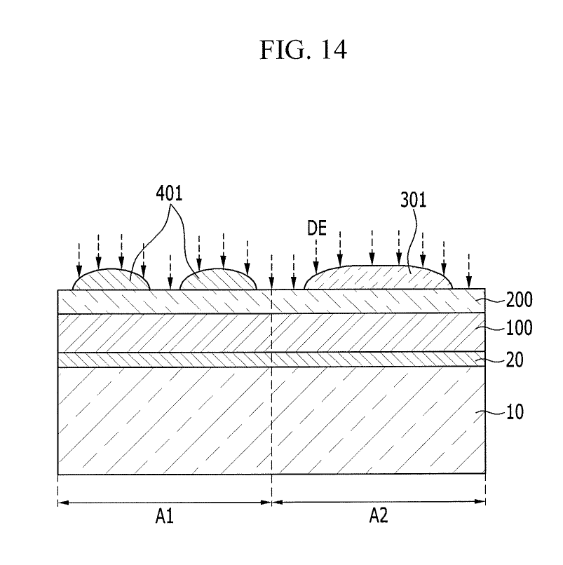

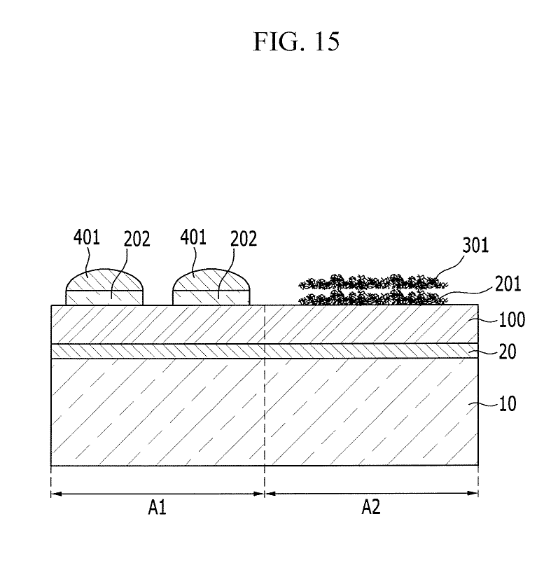

Then, as shown in FIG. 14 and FIG. 15, the conductive layer 200 is dry-etched (DE) using the photoresist patterns 401 and the organic pattern 301 as masks such that first conductive patterns 202 and a second conductive pattern 201 are formed (S350).

In detail, the conductive layer 200 is dry-etched using the photoresist patterns 401 and the organic pattern 301 as masks so as to form the first conductive patterns 202 and the second conductive pattern 201. In this case, the dry-etching is performed throughout the substrate 100 using an etching means such as ions or plasma, and when the dry-etching is performed, an organic material included in the photoresist patterns 401 is not eliminated by the dry-etching and an organic material included in the organic pattern 301 is substantially eliminated by the dry-etching such that the plurality of fillers condensed in the network shape are used as a mask, and accordingly the dry-etched first conductive patterns 202 have flat surfaces and the shapes of the plurality of fillers condensed in the network shape are directly transferred as a shape of the second conductive pattern 201. Thus, the second conductive pattern 201 is formed in the shape of the nano-sized fillers condensed in the network shape.

The conductive layer 200 is dry-etched using the photo-resist patterns 401 and the organic pattern 301 as masks so as to form the first conductive patterns 202 in the first area A1 and the second conductive pattern 201 to which the shapes of the plurality of fillers condensed in the network shape in the second area A2 are transferred.

Meanwhile, the conductive layer 200 is dry-etched using the photoresist pattern 401 and the organic pattern 301 as masks, and then dry-etching is performed throughout the substrate 100 to form the first conductive pattern 202 and the second conductive pattern 201 to which the shapes of the plurality of fillers condensed in the network shape are transferred.

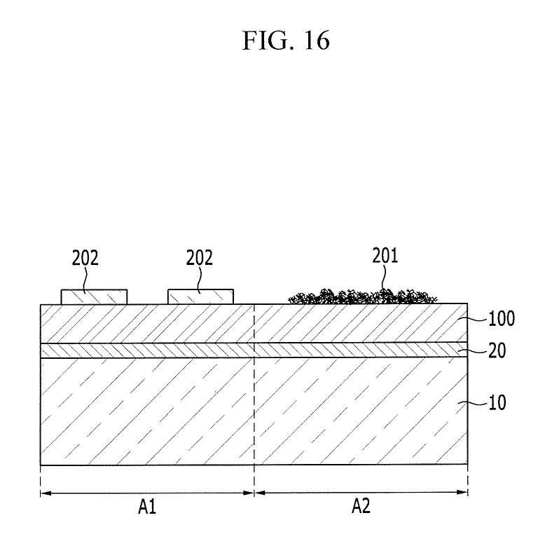

Then, as shown in FIG. 16, the photoresist pattern 401 and the organic pattern 301 are eliminated (S450).

In detail, a residual of the photoresist pattern 401 and the organic pattern 301 that includes the plurality of fillers 310 are eliminated through an ashing process that uses plasma and the like such that the first conductive patterns 202 and the second conductive pattern 201 are exposed.

An electronic device according to an exemplary embodiment of the present invention can be manufactured by detaching the substrate 100 from the support substrate 10.

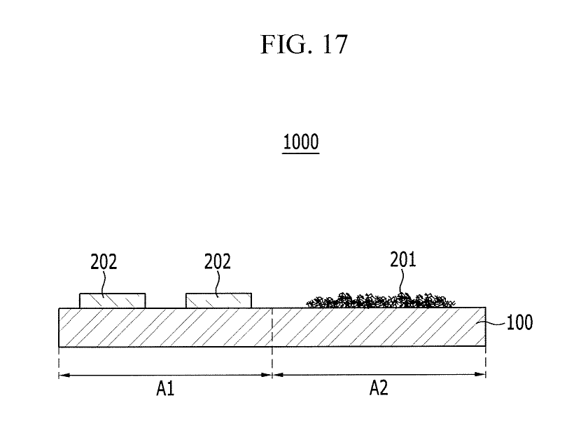

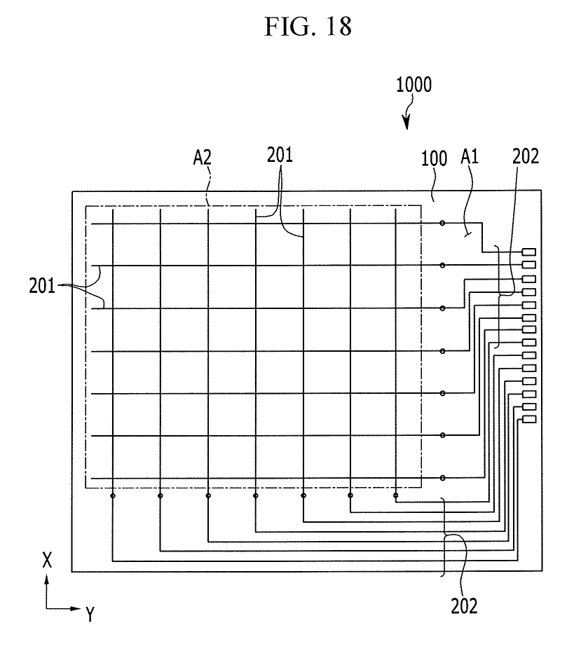

An electronic device according to an exemplary embodiment of the present invention will be described with reference to FIG. 17 and FIG. 18. The electronic device according an exemplary embodiment of the present invention can be manufactured using a method for forming a conductive pattern according to an exemplary embodiment of the present invention.

FIG. 17 is a cross-sectional view of a section of an electronic device according to an exemplary embodiment of the present invention.

As shown in FIG. 17, an electronic device 1000 according to an exemplary embodiment of the present invention includes a substrate 100, first conductive patterns 202, and a second conductive pattern 201.

The substrate 100 is foldable and flexible. The flexible substrate 100 may include a resin film such as a polyimide or a polycarbonate.

The first conductive patterns 202 are located in a first area A1 of the substrate 100, and have flat surfaces. The first conductive patterns 202 may be made of the same material as the second conductive pattern 201.

The second conductive pattern 201 is located in a second area A2, and has a shape transferred from the shape of a plurality of nano-sized fillers condensed in a network shape. The second conductive pattern 201 may include a transparent conductive material such as indium tin oxide (ITO) and indium zinc oxide (IZO), or a metallic conductive material such as gold (Au), silver (Ag), molybdenum (Mo), aluminum (Al), and the like.

FIG. 18 is a top plan view of the electronic device of FIG. 17.

As shown in FIG. 18, an electronic device 1000 according to an exemplary embodiment of the present invention includes a second area A2 that is a touch area where touch is recognized, and a first area which is an outer area neighboring the touch area.

The second conductive patterns 201 form capacitive touch pads that cross each other, and the first conductive patterns 202 form wires connected with ends of the touch pads.

As described, the electronic device 1000 according to an exemplary embodiment of the present invention includes the flexible substrate 100 so that the second area A2, which is a touch area where touch is recognized, can be folded. The second area A2 of the folded electronic device 1000 has a very small curvature radius, and thus high stress is applied to the second conductive patterns 201 at the second area A2. However, the stress applied to the conductive patterns 201 can be dispersed because the shapes of the conductive patterns 201 are transferred from the shapes of the plurality of nano-sized fillers condensed in a network shape, and thus the conductive patterns 201 can be prevented from being damaged. In particular, although the second conductive patterns 201, which are the touch pads, include indium tin oxide or indium tin oxide, which may otherwise be more susceptible to stress damage as compared to a metal such as silver (Ag), the second conductive patterns 201 have the shape transferred from the shapes of the plurality of nano-sized fillers condensed in the network shape so that the stress applied to the second conductive patterns 201 is dispersed, thereby protecting the second conductive patterns 201 from damage.

In addition, when the second conductive patterns 201 form a rhombus-shaped capacitive pad, a touch pad having a wide area may be particularly susceptible to stress. However, the second conductive patterns 201 have the shape transferred from the shapes of the plurality of nano-sized fillers condensed in the network shape so that the stress applied to the second conductive patterns 201 is dispersed, thereby protecting the second conductive patterns 201 from damage.

Further, since the first conductive patterns 202 have a single plate shape having a flat surface, electrical conductivity is higher than that of the second conductive patterns 201 so that signals passing through the first conductive patterns 202, which are the wires, are not overly delayed.

The electronic device 1000 according to an exemplary embodiment of the present invention may be a touch panel. However, according to exemplary embodiments of the present invention, the electronic device 1000 may alternatively be a display device that is not touch-sensitive. In this case, the first conductive patterns may form wires of an outer area and the second conductive patterns may form pixel electrodes.

As described, the approaches discussed above for forming conductive patterns may result in a second conductive pattern 201 that is particularly resilient to stress caused by bending of the flexible substrate 100.

While this invention has been described in connection with what is presently considered to be practical exemplary embodiments, it is to be understood that the invention is not limited to the disclosed embodiments, but, on the contrary, is intended to cover various modifications and equivalent arrangements.

What is claimed is:

1. A method for forming a conductive pattern, comprising:
forming a conductive layer on a substrate;
forming an organic pattern on the conductive layer, the organic pattern including a plurality of fillers condensed in a network shape, wherein the fillers are discrete particles or discrete wires;
forming a conductive pattern by dry-etching the conductive layer using the organic pattern as a mask such that the formed conductive pattern has a shape of the fillers arranged in the network; and
removing the organic pattern.

2. The method of claim 1, wherein the conductive layer comprises a transparent conductive material.

3. The method of claim 1, wherein the plurality of fillers comprise a metal.

4. The method of claim 3, wherein the metal is silver (Ag).

5. The method of claim 3, wherein the condensed network shape of the plurality of fillers include a set of discrete clusters of the filler.

6. The method of claim 5, wherein the plurality of fillers includes nanoparticles or nanowires.

7. The method of claim 1, wherein the organic pattern comprises a photoresist material.

8. The method of claim 1, wherein the forming of the organic pattern comprises:
forming an organic layer, including the plurality of fillers, on the substrate;
condensing the plurality of fillers into the network shape by heating the organic layer; and
patterning the organic layer into the organic pattern.

9. The method of claim 1, wherein the substrate is a foldable and flexible substrate.

10. An electronic device comprising:
a substrate; and
a conductive pattern disposed on the substrate,
wherein the conductive pattern has a shape transferred thereon, the shape including a plurality of discrete particles or discrete wires arranged in a set of discrete clusters.

11. The electronic device of claim 10, wherein the conductive pattern comprises a transparent conductive material.

12. The electronic device of claim 11, wherein the discrete particles are nanoparticles and the discrete wires are nanowires.

13. The electronic device of claim 10, wherein the substrate is foldable and flexible.

14. A method for forming a conductive pattern, comprising:
forming a conductive layer on a substrate;
forming a photoresist pattern in a first area of the conductive layer;
forming an organic pattern in a second area of the conductive layer, the organic pattern including a plurality of fillers condensed in a network shape;
forming a first conductive pattern in the first area by dry-etching the conductive layer using the photoresist pattern and the organic pattern as masks;
forming a second conductive pattern in the second area, including transferring the shapes of the plurality of fillers condensed in the network pattern; and
removing the photoresist pattern and the organic pattern.

15. The method of claim 14, wherein the forming of the photoresist pattern and the organic pattern comprises:
forming a photoresist layer on the substrate;
forming the photoresist pattern in the first area of the substrate by exposing and developing the photoresist layer;
forming an organic layer including the plurality of fillers on the substrate;
condensing the plurality of fillers into the network shape by heating the organic layer; and
forming the organic pattern in the second area of the substrate by patterning the organic layer.

16. An electronic device comprising:
a substrate including a first area and a second area thereof;
a first conductive pattern located in the first area of the substrate; and
a second conductive pattern located in the second area of the substrate,
wherein the second conductive pattern has a shape transferred thereon, the shape including a plurality of fillers condensed in a network shape.

17. The electronic device of claim 16, wherein the surface of the first conductive pattern is flat.

18. The electronic device of claim 16, wherein the second area is a touch-sensitive area where touch is recognized, and the first region is an outer area neighboring the touch area.

19. The electronic device of claim 18, wherein the second conductive pattern forms a touch pad, and the first conductive pattern forms a wire connected with an end of the touch pad.

20. A method for forming a conductive pattern on a flexible substrate, comprising:
forming a conductive layer on a flexible substrate
forming an organic pattern on the conductive layer, the organic pattern including a plurality of nanoparticles or nanowires suspended in an overcoat material;
condensing the plurality of nanoparticles or nanowires into a set of discrete clusters;
forming a conductive pattern from the conductive layer by etching the conductive layer using the organic pattern as a mask such that the conductive pattern has a shape of the clusters of nanoparticles or nanowires; and
removing the organic pattern from the substrate.
